(19) United States
(12) Patent Application Publication
(10) Pub. No.: US 2025/0107117 A1
(43) Pub. Date: Mar. 27, 2025

(54) SCHOTTKY DIODE WITH LOW REVERSE CURRENT AND HIGH HEAT DISSIPATION EFFECT

(71) Applicant: PANJIT INTERNATIONAL INC., KAOHSIUNG CITY (TW)

(72) Inventors: CHUNG-HSIUNG HO, KAOHSIUNG CITY (TW); CHI-HSUEH LI, TAINAN CITY (TW); CHIA-WEI CHEN, KAOHSIUNG CITY (TW); YU-MING HSU, KAOHSIUNG CITY (TW); WEN-LIANG HUANG, KAOHSIUNG CITY (TW); MING-KUN HSIN, KAOHSIUNG CITY (TW); SHIH-MING CHEN, KAOHSIUNG CITY (TW)

(21) Appl. No.: 18/509,657

(22) Filed: Nov. 15, 2023

(30) Foreign Application Priority Data
Sep. 23, 2023 (TW) 112136477

(51) Int. Cl. H01L 29/872; H01L 29/06

(52) U.S. Cl. CPC H10D 8/60; H10D 62/103

(57) ABSTRACT

A Schottky diode includes a substrate with an epitaxy layer on which a cathode region and an anode region are defined. A cathode structure and an anode structure are formed in the cathode region and the anode region respectively and horizontally separated by a distance. The anode structure includes a plurality of p-type doped regions diffused from the epitaxy layer toward the substrate, with an interval is formed between adjacent two p-type doped regions. A backside metal film and a backside protection layer are sequentially formed on a back surface of the substrate. Since the manufacturing of the Schottky diode does not involve wire bonding and molding processes, the overall thickness of the Schottky diode is reduced and heat dissipation is improved. With the backside metal film on the back side of the substrate, an equivalent resistance and a forward voltage of the Schottky diode can be reduced.

### CROSS REFERENCE TO RELATED APPLICATIONS

This non-provisional application claims the benefit under 35 U.S.C. § 119(a) to Patent Application No. 112136477 filed in Taiwan on Sep. 23, 2023, which is hereby expressly incorporated by reference into the present application.

### BACKGROUND OF THE INVENTION

### 1. Field of the Invention

The present invention relates to a Schottky diode, particularly to a Schottky diode having low reverse current and high heat dissipation effect.

### 2. Description of the Related Art

With a metal-semiconductor junction therein, Schottky diode has the significant advantage of high-speed switching and is suitable for power rectifying devices. However, the drawback of high leakage current still limits the applications of the Schottky diode.

With reference to FIG. 7, a Schottky diode package in accordance with the prior art may comprise a diode chip 71 having a vertical configuration, which includes an n-type doped layer 72 and a metal layer 73 formed under the n-type doped layer 72.

The diode chip 72 needs to be further protected through a packaging process, which usually involves steps of attaching the metal layer 73 onto a first lead 74 of a lead frame, electrically connecting a contact on the n-type doped layer 72 to a second lead 75 of the lead frame, and encapsulating the diode chip 72 in an encapsulant 76.

Since the Schottky diode package is manufactured through the foregoing steps such as die attaching, wire bonding and molding to embed the diode chip 72 in the encapsulant 76, heat dissipation capability of the Schottky diode package will be limited. Further, the overall size of the Schottky diode package is difficult to be reduced due to the thickness of the lead frame, a loop height of the boding wire, the thickness of the encapsulant 76, etc.

### SUMMARY OF THE INVENTION

An objective of the present disclosure is to provide a Schottky diode and manufacturing method of the same to improve the reverse current and heat dissipation effect.

The Schottky diode comprises:
a substrate having an epitaxy layer, wherein the epitaxy layer is partitioned into a cathode region and an anode region beside the cathode region;
a backside metal film formed on a back surface of the substrate;
a cathode structure formed in the cathode region of the substrate and comprising:
   a heavily doped n-type region diffusing from a surface of the epitaxy layer into the substrate;
   a lightly doped n-type region formed in the epitaxy layer and around the highly doped n-type region; and
   a cathode contact formed on and contacting the heavily doped n-type region, wherein the cathode contact is composed of multiple stacked metal material layers; and
an anode structure, electrically insulated from the cathode structure, formed in the anode region of the substrate, and comprising:
   a plurality of p-type doped regions, each p-type doped region diffusing from the surface of the epitaxy layer into the substrate, wherein each adjacent two of the p-type doped regions P+ are separated by an interval; and
   an anode contact formed on and contacting the plurality of the p-type doped regions, wherein the anode contact protrudes from the substrate and is composed of multiple stacked metal material layers.

For the anode structure of the Schottky diode, a plurality of p-type doped regions is formed in the substrate to provide multiple depletion regions between the p-n junctions. When a reverse voltage is applied to the Schottky diode, the narrow channel between adjacent depletion regions can limit the reverse currents of the Schottky diode.

Further, the Schottky diode is manufactured based on WLCSP process without using the lead frame and performing conventional processes such as die attaching, wire bonding, encapsulant molding, etc., so that the overall thickness of the Schottky diode is reduced and the heat dissipation effect is improved.

By forming the backside metal film on the back surface of the substrate, the equivalent resistance of the Schottky diode will be reduced. Accordingly, the forward voltage of the Schottky diode, which is positively correlated to the equivalent resistance Rt, would be lowered.

Other objectives, advantages and novel features of the invention will become more apparent from the following detailed description when taken in conjunction with the accompanying drawings.

### BRIEF DESCRIPTION OF THE DRAWINGS

FIGS. 1A to IF are cross sectional views showing processes for manufacturing a cathode of a Schottky diode in accordance with the present invention;

FIGS. 2A to 2E are cross sectional views showing processes for manufacturing an anode of a Schottky diode in accordance with the present invention;

FIGS. 3A to 3G are cross sectional views showing processes for packaging the Schottky diode in accordance with the present invention;

FIG. 4 is a cross sectional view of the Schottky diode in accordance with the present invention;

FIG. 5 shows reverse currents in the Schottky diode when a reverse voltage is applied to the Schottky diode in accordance with the present invention;

FIG. 6 shows the flowing of a forward current of the Schottky diode in accordance with the present invention; and

FIG. 7 is a cross sectional view of a conventional Schottky diode package.

### DETAILED DESCRIPTION OF THE INVENTION

A Schottky diode in accordance with the present invention comprises a cathode and an anode both being fabricated on the same side of a substrate, so that the cathode and the anode are arranged in a horizontal configuration instead of a vertical configuration. The manufacturing processes of the cathode and the anode are described as follows and shown by the drawings. It is noted that the order of manufacturing processes of the cathode and the anode may be exchangeable, not limited to the sequence as described in the specification. The Schottky diode of the present invention is manufactured on a wafer substrate through the wafer-level chip packaging technology (WLCSP).

### Cathode Forming Processes:

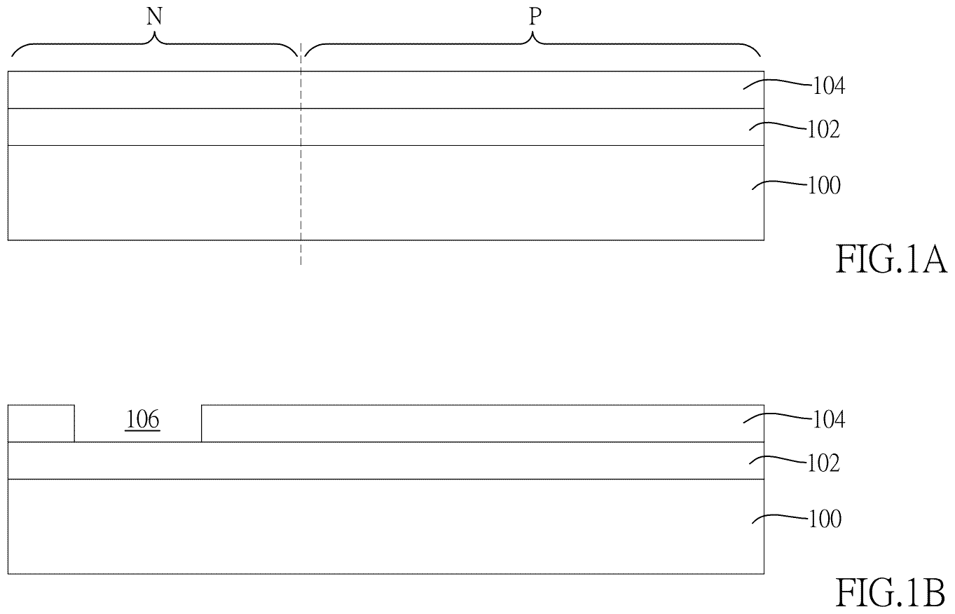

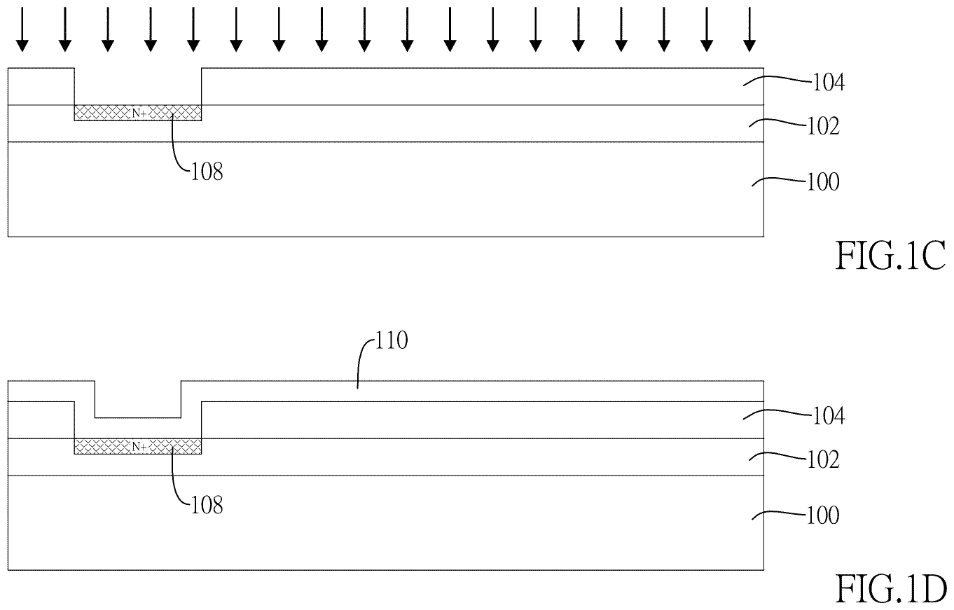

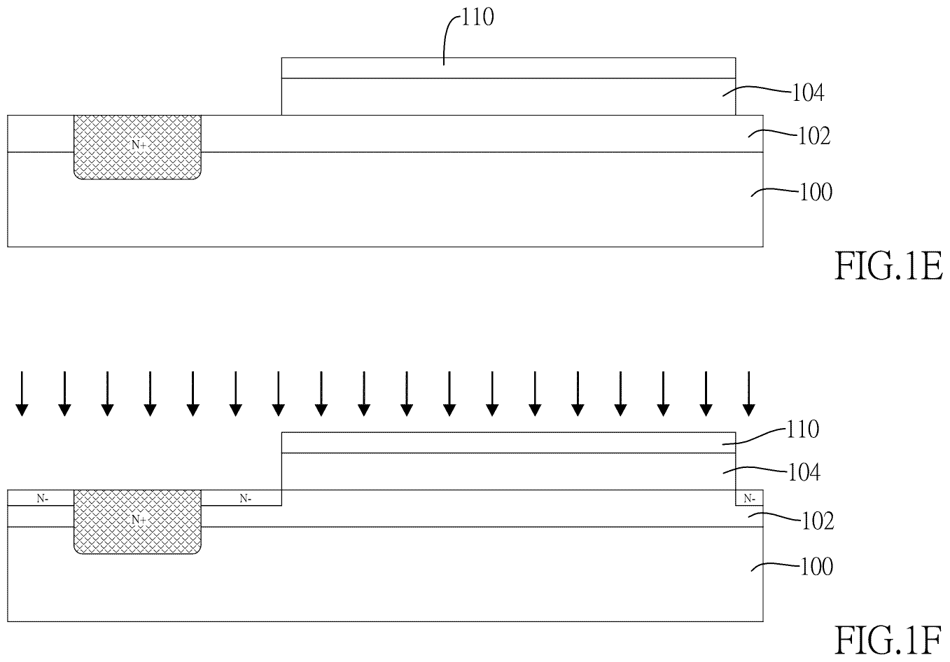

With reference to FIG. 1A, a semiconductor substrate 100 is used to manufacture multiple Schottky diodes having the same structure in accordance with the present invention, wherein the drawings only illustrate a Schottky diode as an example. The semiconductor substrate 100 such as a silicon wafer is defined to include a cathode region (N) and an anode region (P) for respectively manufacturing a cathode and an anode of a Schottky diode. In this embodiment, an epitaxy layer 102 is grown on a top surface of the substrate 100 and an oxide protection layer 104 is subsequently formed on the epitaxy layer 102.

With reference to FIG. 1B, a cathode pattern window 106 is formed by removing a portion of the oxide protection layer 104 through the photolithography processes so that the epitaxy layer 102 can be exposed from the cathode pattern window 106. The oxide protection layer 104 in the anode region (P) remains on the substrate 100.

With reference to FIG. 1C, a doping process such as the ion implantation process is performed to dope the substrate 100 with high concentration n-type material dopants, for example phosphorus ions. As shown in this embodiment, the n-type material ions are implanted into the epitaxy layer 102 exposed from the cathode pattern window 106 to form a first implantation area 108 in the epitaxy layer 102.

With reference to FIG. 1D, a deposition process is performed on the substrate 100 to form a first dielectric layer 110. The material of the first dielectric layer 110 may be selected from tetraethoxysilane (TEOS).

With reference to FIG. 1E, the substrate 100 is further treated by an annealing process so that the n-type dopants in the first implantation area 108 can be distributed outward through thermal diffusion to form a highly doped n-type region N+. The substrate 100 is also patterned by the photolithography process to remove a part of the oxide protection layer 104 and the first dielectric layer 110 above the highly doped n-type region N+. Accordingly, the epitaxy layer 102 and the highly doped n-type region N+ are exposed from the cathode region (N). The photolithography process also removes a portion of the oxide protection layer 104 and the first dielectric layer 110 near an edge of the anode region (P).

With reference to FIG. 1F, another doping process is performed to dope the epitaxy layer 102 and the highly doped n-type region N+, which are uncovered by the oxide protection layer 104 and the first dielectric layer 110, with low concentration n-type material dopants to form a lightly doped n-type region N−. The dopant such as phosphorus ions, having a concentration lower than that being implanted into the highly doped n-type region N+, are injected into the lightly doped n-type region N−.

In this embodiment, the manufacturing of the anode region (P) is followed by manufacturing of the cathode region (N). In other embodiments, the manufacturing process of the anode region (P) may be performed prior to that of the cathode region (N).

### Anode Forming Processes:

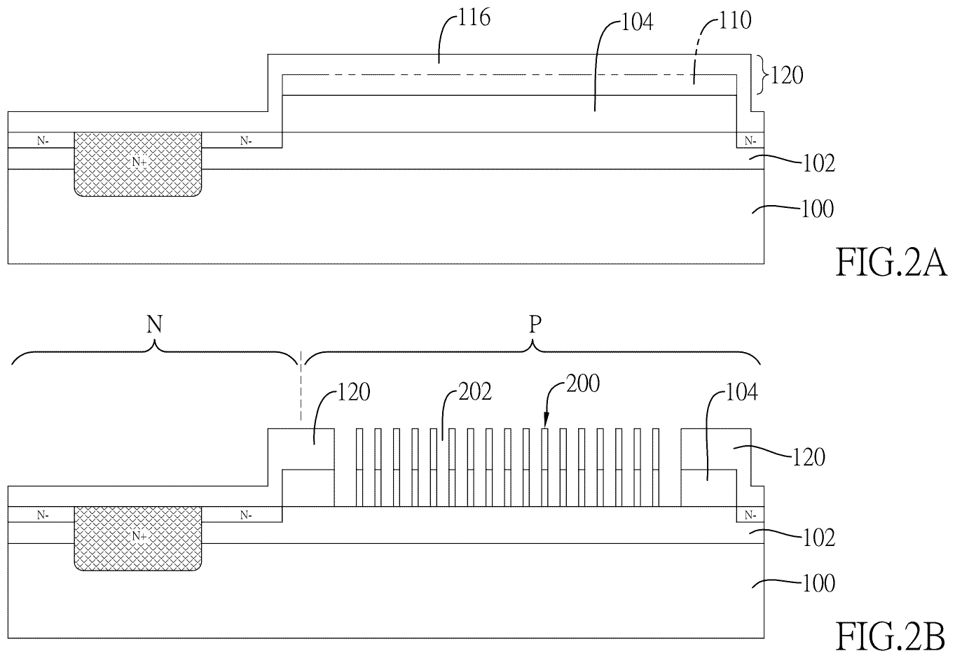

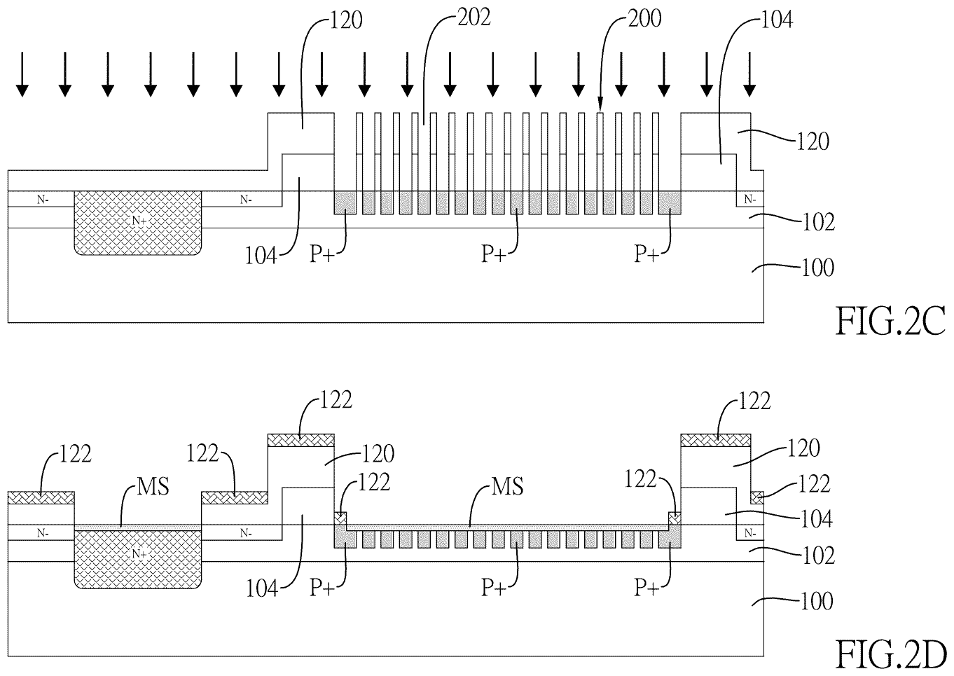

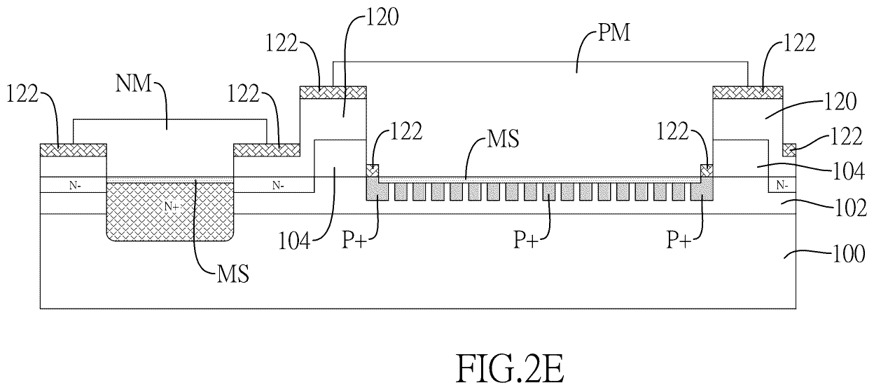

With reference to FIG. 2A, a second dielectric layer 116 such as tetraethoxysilane (TEOS) is applied to cover the surface of the substrate 100, wherein the second dielectric layer 116 overlaps the first dielectric layer 110 and the lightly doped n-type region N−. In the following description, the first dielectric layer 110 and the second dielectric layer 116 are collectively referred to as a dielectric protection layer 120.

With reference to FIG. 2B, the dielectric protection layer 120 as well as the oxide protection layer 104 in the anode region (P) are patterned so that the dielectric protection layer 120 and the oxide protection layer 104 form a plurality of upright grille barriers 200 separated from each other. A groove 202 is formed between two adjacent barriers 200 and the epitaxy layer 102 can be exposed from a bottom of each groove 202. It is noted that the dielectric protection layer 120 as well as the oxide protection layer 104 next to the cathode region (N) still remain on the substrate 100 as an insulation layer between the anode and the cathode.

With reference to FIG. 2C, the substrate 100 is doped with a high concentration p-type material such as boron ions in the anode region (P). The p-type material can be injected into the epitaxy layer 102 through the grooves to form a plurality of p-type doped regions P+ spaced apart from one another. Each adjacent two p-type doped regions P+ are separated by an interval.

With reference to FIG. 2D, after forming the p-type doped regions P+, the plurality of barriers 200 is removed by etching. Both the dielectric protection layer 120 and the oxide protection layer 104 next to the cathode region (N), and both the dielectric protection layer 120 and the oxide protection layer 104 near the edge of anode region (P) are not etched. A metal silicide layer MS is further provided on the exposed epitaxy layer 102 in the cathode region (N) and the anode region (P) to effectively reduce the junction resistance between the epitaxy layer 102 and metal material subsequently formed. Further, a third dielectric layer 122 may be formed on the dielectric protection layer 120 and around the periphery of the metal silicide layer MS in the anode region (P).

With reference to FIG. 2E, an anode conductive layer PM and a cathode conductive layer NM are respectively formed on the surfaces of the metal silicide layers MS in the anode region (P) and the cathode region (N). The anode conductive layer PM and the cathode conductive layer NM may be formed by composite material or by stacking different metal layers. In one embodiment, the anode conductive layer PM and the cathode conductive layer NM are substantially composed of an aluminum material.

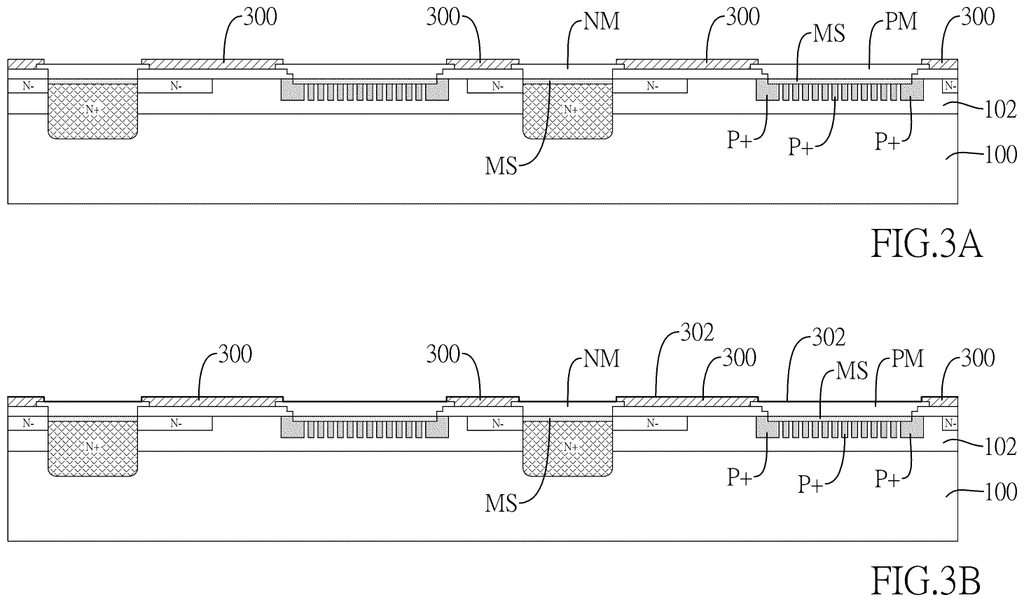

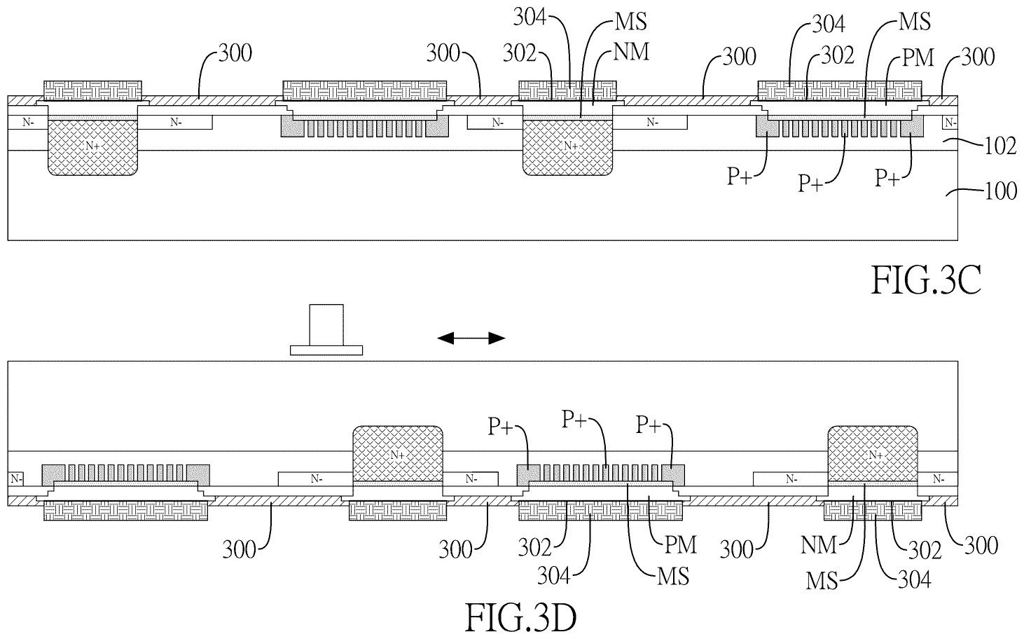

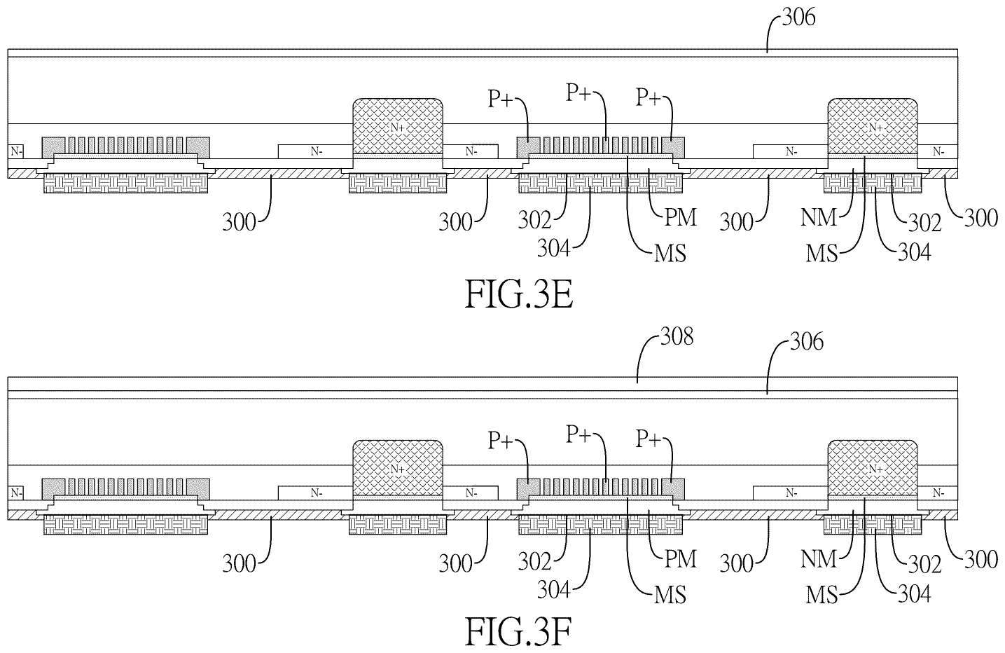

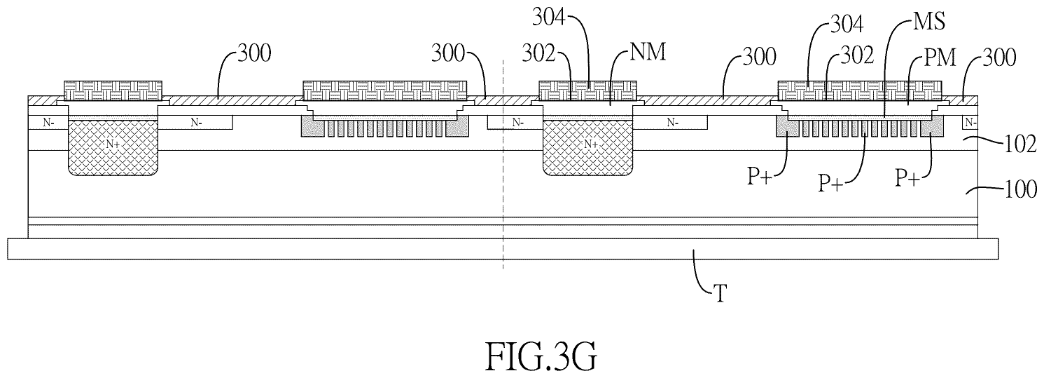

After the step as shown in FIG. 2E, the major structure of the Schottky diode wafer of the present invention has been completed. The Schottky diode wafer in FIG. 2E will be further processed through the steps shown in FIGS. 3A-3G and described as follows, i.e. the wafer level chip scale process (WLCSP), wherein illustrations of some aforementioned components of the Schottky diode may be simplified in the drawings.

With reference to FIG. 3A, for each of the Schottky diodes, a surface dielectric layer 300 is provided over the regions other than the anode conductive layer PM and the cathode conductive layer NM. The surface dielectric layer 300 may be the polyimide (PI) film.

With reference to FIG. 3B, a seed layer 302 is formed over the substrate 100. In this embodiment, a seed layer 302 of titanium/copper (Ti/Cu) comprehensively covers the anode conductive layer PM, the cathode conductive layer NM and the surface dielectric layer 300 by sputtering.

With reference to FIG. 3C, after forming the seed layer 302, a contact metal layer 304 such as copper layer, Ti/Cu, and Cu/Sn can be formed on the seed layer 302, and an optional tin film (not shown) may be further plated over the contact metal layer 304. The contact metal layer 304 is patterned to cover the contact metal layers 304 on the anode conductive layer PM and the cathode conductive layer NM. The contact metal layer 304 as well as the seed layer 302 in another area will be removed from the substrate 100.

With reference to FIG. 3D, the substrate 100 is turned over for back surface processing. The back surface of the substrate 100 is flattened by grinding to obtain a relatively laminate back surface. By grinding the back surface of the substrate 100, the thickness of the substrate 100 can be trimmed to a desired value.

With reference to FIGS. 3E and 3F, a backside metal film 306 is formed on the back surface of the substrate 100. In this embodiment, a TiNiAg or TiCu composite metal layer is sputtered to comprehensively cover the back surface of the substrate 100.

A backside protection layer 308 is further stacked on the backside metal film 306. Identification marks, texts, symbols, etc. can be formed on the backside protection layer 308 by laser marking process. The backside metal film 306 is provided to reduce the forward voltage of the Schottky diode instead of acting as a contact for electrical connection in the conventional Schottky diode. Therefore, the backside metal film 306 has no electrical connection to the anode conductive layer PM.

With reference to FIG. 3G, a carrier film 306 is temporarily attached onto the backside protection layer 308 and the substrate 100 is cut along predetermined cutting paths as indicated by broken lines between two neighboring Schottky diodes to obtain multiple separated Schottky diodes.

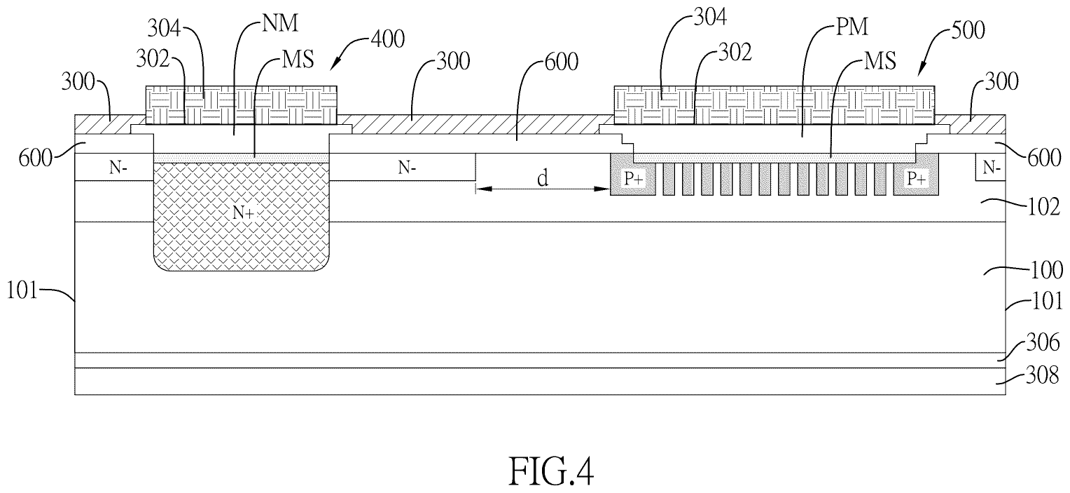

As shown in FIG. 4, each Schottky diode manufactured by the foregoing method of the present invention mainly comprises a substrate 100, a cathode structure and an anode structure.

The substrate 100 includes an epitaxy layer 102 having a surface as an active surface on which a cathode region (N) and an anode region (P) are defined, wherein the cathode structure and the anode structure are respectively formed in the cathode region (N) and the anode region (P). The back surface of the substrate 100 is covered by a backside metal film 306 and a backside protective film 308 overlapped on the metal film 306. The periphery sidewalls 101 of the substrate 100 are exposed without being covered by any encapsulant.

The cathode structure includes a highly doped n-type region N+, a lightly doped n-type region N− and a cathode contact 400.

The highly doped n-type region N+ diffuses from the surface of the epitaxy layer 102 into the substrate 100.

The lightly doped n-type region N− is formed in the epitaxy layer 102 and around the highly doped n-type region N+, wherein the doping concentration of the lightly doped n-type region N− is less than that of the highly doped n-type region N+. The lightly doped n-type region N− extends into the substrate 100 in a depth smaller than the highly doped n-type region N+ does.

The cathode contact 400 is formed on and contacts the highly doped n-type region N+. The cathode contact 400 protrudes from the surface of the substrate 100 and includes a plurality of stacked metal layers, such as a metal silicide layer MS, an aluminum material-based cathode conductive film NM, and a contact metal layer 304.

The anode structure includes a plurality of p-type doped regions P+ and an anode contact 500.

Each p-type doped region P+ diffuses from the surface of the epitaxy layer 102 into the substrate 100 and spaced apart from one another by an interval. The outermost p-type doped region P+ is away from the lightly doped n-type region N− by a lateral distance d.

The anode contact 500 is formed on and contacts the plurality of p-type doped regions P+. The anode contact 500 protrudes from the surface of the substrate 100 and includes stacked metal layers, such as a metal silicide layer MS, an aluminum material-based anode conductive film PM, and a contact metal layer 304.

The cathode structure is electrically insulated from the anode structure. To achieve the insulation, a surface insulative layer is provided on the substrate 100. The surface insulative layer includes the surface dielectric layer 300 as well as a composite dielectric layer 600 that comprises the oxide protection layer 104, the first dielectric layer 110, the second dielectric layer 116 and the third dielectric layer 122 described above.

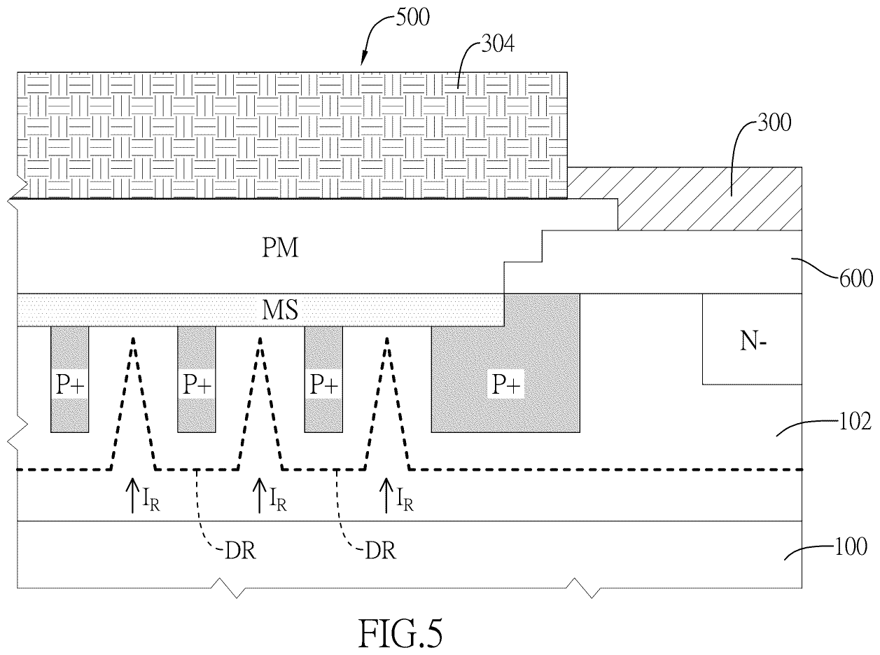

With reference to FIG. 5, when a reverse voltage is applied across the anode and the cathode of the Schottky diode, there are reverse currents IR flowing from the n-type material to the p-type material. Because a plurality of p-type doped regions P+ is formed in the n-type material epitaxy layer as the anode structure, a lot of depletion regions DR will inherently form between the p-n junctions. A channel between two adjacent depletion regions DR can be narrowed or even pinched, thereby reducing the reverse currents IR.

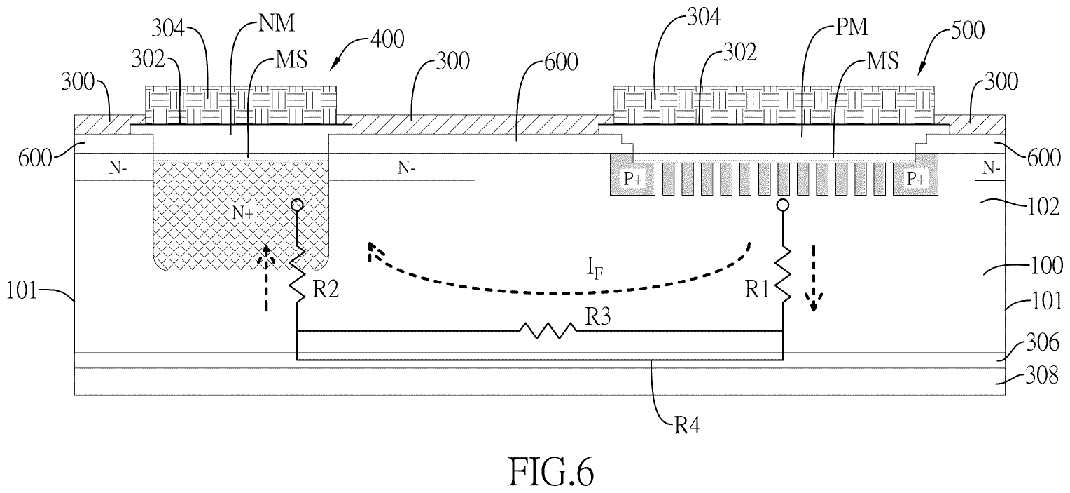

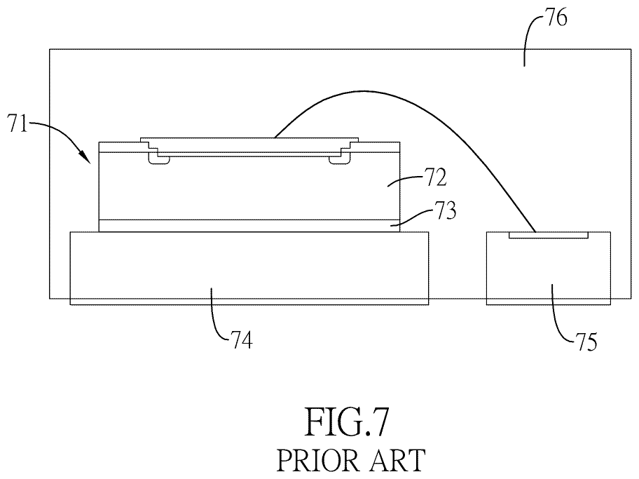

With reference to FIG. 6, when a forward voltage is applied across the anode and the cathode, there is a forward current IF in the Schottky diode. An equivalent resistance Rt of the Schottky diode may be expressed as follows:

$$Rt = R 1 + Rbase + R 2$$

R1 is an equivalent resistance between the anode contact 500 and the substrate 100. R2 is an equivalent resistance between the cathode contact 400 and the substrate 100. Rbase is regarded as an equivalent resistance of R3 and R4 connected in parallel, where R3 is the resistance of the substrate 100, i.e. the impedance of the silicon substrate itself, and R4 is the resistance of the backside metal film 306 on the back surface of the substrate 100.

Because the resistance R4 of the backside metal film 306 is relatively low, Rbase will be much lower than R3 by connecting R3 and R4 in parallel. In other words, by providing a backside metal film 306 on the back surface of the substrate 100, the Rbase can be effectively decreased.

Once the Rbase has been reduced, the equivalent resistance Rt of the Schottky diode accordingly can be lowered. Therefore, the forward voltage VF=IF×Rt of the Schottky diode is diminished.

In short, the Schottky diode in accordance with the present invention has the features as follows.

1. Both the anode and cathode structures are configured horizontally on the same surface of the substrate, and the Schottky diode is manufactured based on WLCSP process. The Schottky diode can be directly soldered onto a circuit board without using the lead frame. Conventional processes such as die attaching, wire bonding and molding are all omitted.

2. Since the Schottky diode is not encapsulated by conventional encapsulant, the heat dissipation efficiency can be improved.

3. Since the anode structure includes a plurality of p-type doped regions formed therein, depletion regions formed between the p-n junctions are beneficial to reduction of the reverse currents of the Schottky diode.

4. By forming the backside metal film on the back surface of the substrate, the equivalent resistance Rt of the Schottky diode can be reduced. Accordingly, the forward voltage VF correlated to the equivalent resistance Rt can be lowered. Comparing the Schottky diode having the backside metal film composed of TiNiAg with another Schottky diode without the backside metal film on condition that the forwarding currents of 1 amp and 2 amps are applied, the forward voltages VF of the two kinds of Schottky diodes are shown in the following tables 1 and 2. Table 1 and table 2 respectively show the first set of Schottky diodes under test and the second set of Schottky diodes under test.

TABLE 1
First set of Schottky diodes under

| | Forward voltage | Forward voltage | Forward |
|---|---|---|---|
| | (V_{F}) | (V_{F}) | voltage |
| | Without backside | With backside | difference |
| | metal film | metal film | (ΔV_{F}) |
| forward current = | 0.407 V | 0.395 V | 0.012 V |
| 1 amp | | | |
| forward current = | 0.472 V | 0.455 V | 0.017 V |
| 2 amps | | | |

TABLE 2
Second set of Schottky diodes under

| | Forward voltage | Forward voltage | Forward |
|---|---|---|---|
| | (V_{F}) | (V_{F}) | voltage |
| | Without backside | With backside | difference |
| | metal film | metal film | (ΔV_{F}) |
| forward current = | 0.426 V | 0.416 V | 0.010 V |
| 1 amp | | | |
| forward current = | 0.509 V | 0.490 V | 0.019 V |
| 2 amps | | | |

According to the examples disclosed above, it is proved that the forward voltage of the Schottky diode can be effectively reduced when the backside metal film is formed on the back surface of the substrate.

Even though numerous characteristics and advantages of the present invention have been set forth in the foregoing description, together with details of the structure and function of the invention, the disclosure is illustrative only. Changes may be made in detail, especially in matters of shape, size, and arrangement of parts within the principles of the invention to the full extent indicated by the broad general meaning of the terms in which the appended claims are expressed.

What is claimed is:

1. A Schottky diode comprising:
a substrate having an epitaxy layer, wherein the epitaxy layer is partitioned into a cathode region and an anode region beside the cathode region;
a backside metal film formed on a back surface of the substrate;
a cathode structure formed in the cathode region of the substrate and comprising:
a heavily doped n-type region diffusing from a surface of the epitaxy layer into the substrate;
a lightly doped n-type region formed in the epitaxy layer and around the highly doped n-type region; and
a cathode contact formed on and contacting the heavily doped n-type region, wherein the cathode contact is composed of multiple stacked metal material layers; and
an anode structure, electrically insulated from the cathode structure, formed in the anode region of the substrate and comprising:
a plurality of p-type doped regions, each p-type doped region diffusing from the surface of the epitaxy layer into the substrate, wherein each adjacent two of the p-type doped regions P+ are separated by an interval; and
an anode contact formed on and contacting the plurality of the p-type doped regions, wherein the anode contact protrudes from the substrate and is composed of multiple stacked metal material layers.

2. The Schottky diode as claimed in claim 1, wherein a surface insulative layer is formed on the substrate to electrically insulate the cathode structure from the anode structure and is flush with periphery sidewalls of the substrate.

3. The Schottky diode as claimed in claim 2, wherein the surface insulative layer comprises a surface dielectric layer composed of polyimide and a dielectric layer composed of tetraethoxysilane.

4. The Schottky diode as claimed in claim 1, wherein an outermost one of the plurality of the p-type doped regions is spaced apart from the lightly doped n-type region by a lateral distance.

5. The Schottky diode as claimed in claim 1, wherein,
the substrate is a silicon substrate;
the cathode contact comprises a silicide metal film, a cathode conductive layer and a contact metal layer;
the anode contact comprises a silicide metal film, an anode conductive layer and a contact metal layer;
the cathode conductive layer and the anode conductive layer include an aluminum material; and
the contact metal layers of the cathode contact and the anode contact include a copper material.

6. The Schottky diode as claimed in claim 1, wherein the substrate has uncovered periphery sidewalls being directly exposed; and
a backside protective cover is formed on the backside metal film.
